(19) United States
(12) Patent Application Publication
(10) Pub. No.: US 2014/0061036 A1
(43) Pub. Date: Mar. 6, 2014

(54) Hematite Photovoltaic Junctions

(71) Applicant: The Trustees of Boston College, Chestnut Hill, MA (US)

(72) Inventors: Dunwei Wang, Newton, MA (US); Yongjing Lin, Fremont, CA (US); Yang Xu, Edmonton (CA)

(73) Assignee: The Trustees of Boston College, Chestnut Hill, MA (US)

(21) Appl. No.: 14/019,845

(22) Filed: Sep. 6, 2013

Related U.S. Application Data
(60) Provisional application No. 61/697,610, filed on Sep. 6, 2012.

(51) Int. Cl. C25B 1/00; C25B 1/10; H01L 31/18; H01L 31/032

(52) U.S. Cl. CPC C25B 1/003; H01L 31/032; C25B 1/10; H01L 31/18
USPC 204/248; 136/252; 438/95

(57) ABSTRACT

Photochemical devices having hematite photovoltaic junctions and methods for forming such devices are disclosed. In some embodiments, a photovoltaic device includes a substrate and a photovoltaic junction deposited on the substrate, the photovoltaic junction having a n-type hematite and a p-type hematite.

### RELATED APPLICATIONS

This application claims the benefit of and priority to U.S. Provisional Application No. 61/697,610, filed on Sep. 6, 2012, and which is incorporated herein by reference in its entirety.

### STATEMENT OF GOVERNMENT SUPPORT

This invention was made with Government Support under Contract Number DMR1055762 awarded by the National Science Foundation. The Government has certain rights in the invention.

### FIELD

The embodiments disclosed herein relate to photoelectric devices having a metal oxide photovoltaic junction, and methods for making such devices.

### BACKGROUND

Photoelectrochemical (PEC) water splitting offers the capability of harvesting the energy in solar radiation and transferring it directly to chemical bonds for easy storage, transport, and use in the form of hydrogen. Among the various considerations of a PEC system, the choice of photoelectrode materials is especially important because their properties, such as optical absorption characteristics and chemical stability, determine the system's performance. These materials should absorb light broadly, be inexpensive, and be resistant to photo corrosion.

Hematite is a suitable candidate for use in PEC solar splitting devices due to its suitable stability and abundance. Notwithstanding its appeals, hematite presents significant challenges as well. For example, its hole diffusion distance is on the order of a few nanometers (nm), greatly limiting the efficiency of charge collection. Slow charge transfer kinetics at the solid—electrolyte interface is another challenge that needs to be overcome for high efficiencies. Catalysts of various natures have been shown as potential solutions to this issue if deposited properly on the surface of hematite. Yet, another challenge of hematite is the significant mismatch between the band edge positions and the water reduction and oxidation potentials, which greatly limit the achievable efficiency. This mismatch has at least two important implications. First, with the conduction band edge more positive than the potential at which H₂O is reduced to H₂, complete water splitting cannot be achieved without applied biases. Second, the valence band edge is too positive to permit the measurement of high photovoltage for the oxidation of H₂O to O₂, limiting the practical power conversion efficiencies. Typically, high external bias is required to drive water oxidation reaction.

There is still a need in the art for methods and techniques for preparing hematite based devices that address the above-discussed challenges of hematite.

### SUMMARY

Photochemical devices having hematite photovoltaic junctions and methods for forming such devices are disclosed. In some aspects, the present disclosure provides a photovoltaic device that includes a substrate and a photovoltaic junction deposited on the substrate, the photovoltaic junction having a n-type hematite and a p-type hematite.

In some aspects, the present disclosure provides a device for splitting water that includes a first compartment having a first electrode, the electrode comprising a substrate, and a photovoltaic junction deposited on the substrate, the photovoltaic junction having a n-type hematite and a p-type hematite, a second compartment having a second electrode counter to the first electrode, and a semi-permeable membrane separating the first compartment and the second compartment.

In some aspects, the present disclosure provides a method of growing a photovoltaic hematite junctions on a substrate that includes the steps of depositing via a gas phase deposition method a n-type hematite over a substrate, depositing via a gas phase deposition method a p-type hematite over the n-type hematite, and annealing the resulting n-p hematite junction at a temperature selected to preserve the n-type hematite.

In some aspects, the present disclosure provides a photovoltaic device that includes one or more particles, each particle formed from a hematite photovoltaic junction deposited on a substrate and an electrode material in electrical contact with the substrate.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 illustrates an embodiment photovoltaic device of the present disclosure.

FIG. 2 illustrates an embodiment photovoltaic device of the present disclosure

FIG. 3 illustrates an embodiment electrolytic cell for water splitting suitable for use with a dual absorber electrode of the present disclosure.

FIG. 4A illustrates yet another embodiment photovoltaic device of the present disclosure.

FIG. 4B illustrates an embodiment method using the photovoltaic devices presented in FIG. 4A for water splitting.

FIG. 5 presents a schematic diagram of an embodiment method for forming p-h hematite junctions of the present disclosure.

FIG. 6A and FIG. 6B provide Mg-doped hematite characterization data.

FIG. 7 illustrates embodiment procedures for growth of n-Fe₂O₃, p-Fe₂O₃, and n-p Fe₂O₃.

FIG. 8A and FIG. 8B illustrate energy diagrams of a n-p Fe₂O₃ system and a n-Fe₂O₃ system on a simplistic planar geometry (with illumination).

FIG. 9A presents a cross-sectional transmission electron micrograph (TEM) of a hematite junction prepared by methods disclosed herein.

FIG. 9B presents a SEM image of a non-doped iron oxide film on fluorine-doped tin oxide (FTO) substrate.

FIG. 9C presents a SEM image of a doped iron oxide film on fluorine-doped tin oxide (FTO) substrate.

FIG. 10A, FIG. 10B and FIG. 10C illustrate photoelectrochemical (PEC) characterization data of n-type hematite with and without p-type coating prepared by methods disclosed herein.

FIG. 11A and FIG. 11B present results of elemental analysis of Fe₂O₃ with and without Mg doping, respectively, prepared by methods disclosed herein.

FIG. 11C is a magnified view of the Fe 2p region of Fe₂O₃ with (p-Fe₂O₃) and without (n-Fe₂O₃) Mg doping of FIG. 11B.

FIG. 12 presents optical absorption spectra of Fe₂O₃ with and without Mg doping prepared by methods disclosed herein.

FIG. 13A and FIG. 13B demonstrate visualization of the n-p junction within hematite.

FIG. 14 is a comparison of current density data for 20 mm thick n-type hematite film and 25 mm thick n-type hematite film.

FIG. 15 presents a comparison of current density data for Fe₂O₃ with and without MgO capping layer.

FIG. 16A, FIG. 16B and FIG. 16C present a comparison data for photoelectrodes with and without a p-type hematite layer between a n-type hematite layer and substrate.

FIG. 17 illustrates absorbed photon-to-current conversion efficiencies data for iron oxide with and without p-type coating measured at 1V.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

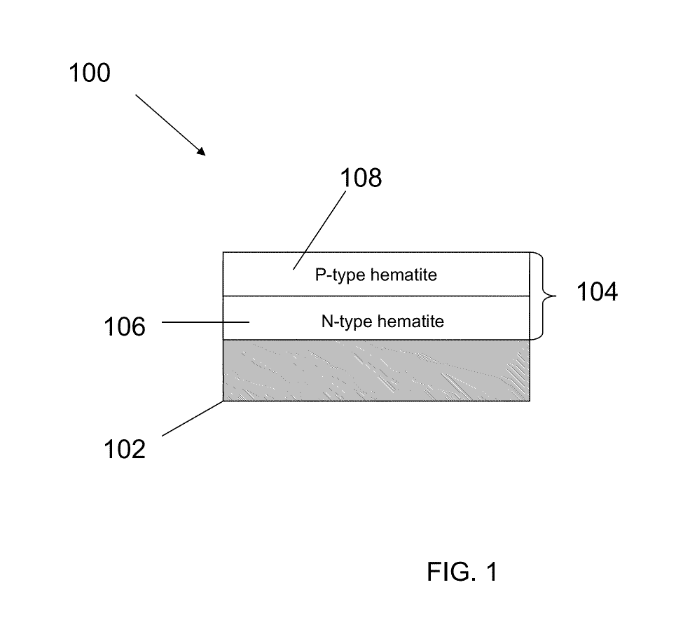

In reference to FIG. 1, in some aspects, the present disclosure provides a photovoltaic device 100 having a substrate 102 on which a metal oxide photovoltaic junction 104, such as a hematite (Fe₂O₃) junction, is deposited. In some embodiments, the junction 104 is a n-p junction comprising a layer of a n-type material and a layer of a p-type material. In some embodiments, the junction 104 is a p-i-n junction comprising a layer of a i-type material between a layer of a n-type material and a layer of a p-type material. In some embodiments, in the photovoltaic hematite junctions of the present disclosure the layer of n-type hematite may be thicker than the layer of the p-type hematite.

In some embodiments, the junction 104 is a homogenous hematite photovoltaic junction comprising a layer of n-type hematite 106 and a layer of p-type hematite 108. Hematite is inherently n-type due to O vacancies. To form p-type hematite, hematite can be doped with a positive dopant, including, by way of non-limiting example, magnesium (Mg), zinc (Zn), copper (Cu), calcium (Ca) or similar dopants. In some embodiments, to form the hematite junction 104, a layer of n-type hematite 106 may be deposited on the substrate 102, followed by a layer of p-type hematite 108. In some embodiments, the layer of n-type hematite may be thicker than the layer of the p-type hematite. In some embodiments, to form the hematite junction 104, a layer of a p-type hematite 108 may be deposited on the substrate 102, followed by a layer of a n-type hematite 106. The sequence of the hematite junction may be selected based on the use of the photovoltaic device 100 of the present disclosure. For example, a hematite junction of a p-type hematite on top of an n-type hematite may be used for water oxidation reaction, while a hematite junction with an n-type hematite on top of a p-type hematite can be used for water reduction reaction.

The ratio of the thickness of the n-type layer to the thickness of the p-type layer determined by the electronic properties of hematite. In some embodiments, the thickness of the hematite may be selected to ensure some potential drop in the p-type layer. If the p-type layer is too thick, significant potential drop may occur within this layer, leading to charge trapping effect. The thickness of n-type hematite may be determined by its optoelectronic properties. In some embodiments, the n-type layer may be about 20 to about 25 nm thick. The ratio of the thickness of the n-type layer to the thickness of the p-type layer can vary depending on the application. In some embodiments, the ratio of the thickness of the n-type layer to the thickness of the p-type layer may be about 4 to 1. For example, in some embodiments, the n-type layer may be about 20 nm thick, while the p-type layer may be about 5 nm thick.

In some embodiments, p-doped hematite (α-Fe2O3) may be synthesized by a vapor deposition method, such as atomic layer deposition (ALD). The resulting material has a hole concentration of ca. 1.7×10¹⁵ cm⁻³. When grown on n-type hematite, the p-type layer creates a built-in field that could be used to assist photoelectrochemical water splitting reactions. The resulting material has a nominal 200 mV turn-on voltage shift toward the cathodic direction, as compared to n-type hematite without a p-type layer.

In some embodiments, a uniform interface is formed between the n-type hematite layer and the p-type hematite layer. In some embodiments, the interface between the layers of hematite is substantially defect free. The structural defect or imperfection may refer to pin-holes or sudden changes of crystal structures, which can be visualized by a transmission telescope microscopy. In some embodiments, the materials have an interface where a defect cannot be found within a 10×10 μm² region. In some embodiments, the interface between the layers of hematite is substantially grain boundary free, due to the ability of the methods of the present disclosure to grow p-type hematite on top of n-type hematite without introducing additional structural defects. The grain boundary refers to the interface that separates different grains of the material.

In some embodiments, the substrate 102 may be formed from a conductive material. In some embodiments, the substrate 102 may be formed from a metal or metal oxide, such as, indium tin oxide (ITO), fluorine doped tin oxide (FTO), and doped zinc oxides, aluminum doped zinc oxide (AZO), silicon (Si), silicides of titanium (TiSi₂), cobalt (CoSi₂), or nickel (NiSi), metal sulfides, such as copper sulfide (Cu₂S), metal oxides, such as copper oxide (Cu₂O), or similar materials. In some embodiments, the substrate may be a semiconductor material. Additional suitable examples of substrates include, but are not limited to, metal substrates such as Ti foil and glass substrates coated with Au, Pt. In some embodiments, non-conductive particles could also be used as substrate for photocatalytic reaction such as to decompose organic contamination.

The substrate 102 may be of various shapes depending on the use of the photovoltaic device 100 of the present disclosure. In some embodiments, the substrate 102 may be planar. In some embodiments, the substrate 102 may be selected from a wire, net, tube, particles, or similar structures. In some embodiments, the substrate 102 may be a nanostructure, such as, a nanowire, nanonet, nanotube, nanoparticle, or another nanostructure.

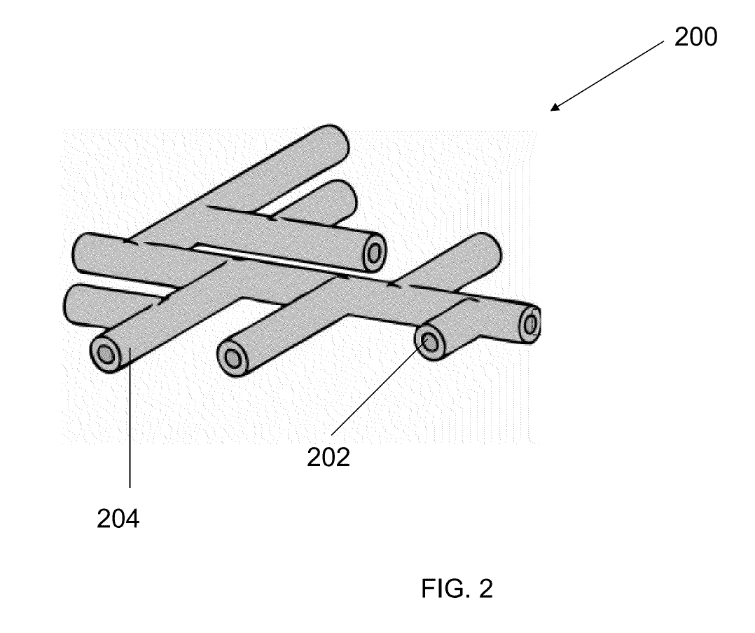

In reference to FIG. 2, by way of a non-limiting example, a photovoltaic device 200 of the present disclosure includes a substrate 202 having a plurality of connected and spaced-apart nanobeams linked together at an angle of about 90°. In some embodiments, the nanobeams are perpendicular or substantially perpendicular to one another. In some embodiments, such substrates may be prepared via a vapor deposition method, such as described in co-pending PCT Application No. PCT/US12/21230, which is incorporated herein by reference in its entirety. The photovoltaic device 200 further comprises a photovoltaic hematite junction 204 deposited over the substrate 202.

In some aspects, the present disclosure provides a method for reducing a turn-on voltage of an electrode for use in a water splitting device that includes forming a photovoltaic junction over the electrode. The photovoltaic junction may be either a homogenous junction or a heterogeneous junction.

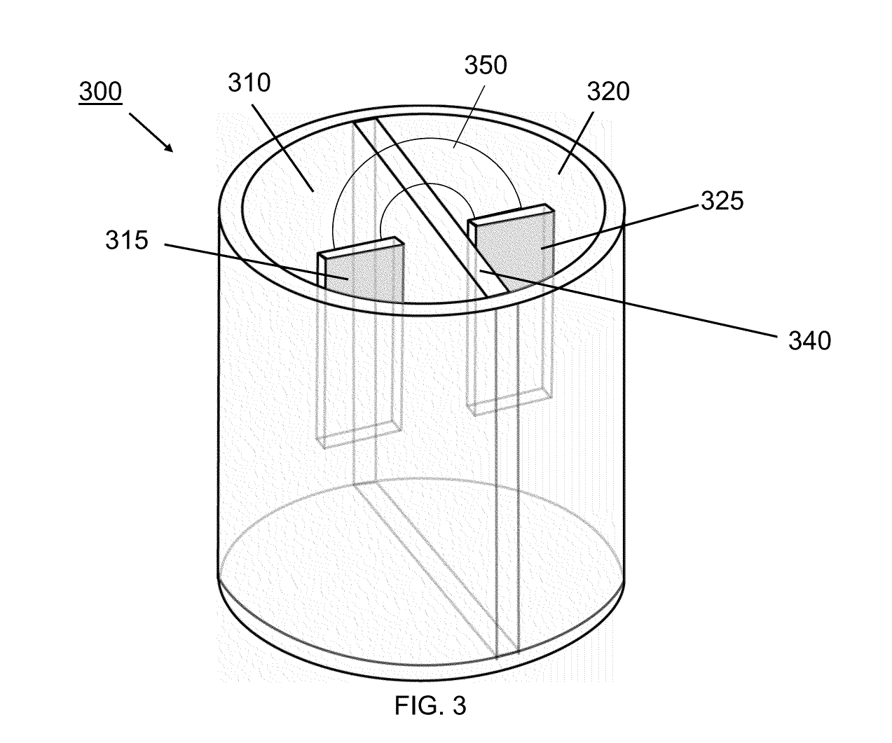

In some embodiments, a method for reducing a turn-on voltage may include forming a photovoltaic junction of p-type hematite and n-type hematite (n-p hematite junction) over a substrate. In some embodiments, the method may be used to prepare an electrode for use in a solar water splitting device. FIG. 3 illustrates an exemplary device 300 of the present disclosure for use in water splitting. The device 300 includes two compartments, 310 and 320, each of which can be used for the half reactions of H₂ and O₂ generations. Solar energy is harnessed to separate charges, which then transfer to the redox pairs in the solutions to perform reactions. The appropriate energy alignment can be enabled by material choices (p-type for H₂ and n-type for O₂) and the adjustment of solution pH. Highly conductive components ensure efficient charge transport, thus completing the full reaction of H₂O splitting. In an embodiment, compartment 310 is filled with an acidic solution, and compartment 320 is filled with a basic solution. Compartments 310 and 320 are separated by a semi-permeable membrane 340 that only allows ionic exchange to balance potential buildup. In an embodiment, the semi-permeable membrane 340 is a charge-mosaic membrane (CMM). In the acidic compartment 310, a p-type material acts to produce H₂ upon illuminations. The device 300 includes electrodes 315 and 325. In some embodiments, one electrode may comprise a substrate and a photovoltaic hematite junction deposited on the substrate of the present disclosure and the other electrode may be made of platinum or similar materials capable of acting as a catalyst for hydrogen generation. The electrodes 315 and 325 can be connected together by external contacts 350 to ensure charge balance. In the solution, opposite charges flow through the semi-permeable membrane 340 to annihilate each other. Both the acidic and the basic solutions should be periodically refreshed by adding more acids or bases to maintain an appropriate chemical potential difference by maintaining a preset PH difference.

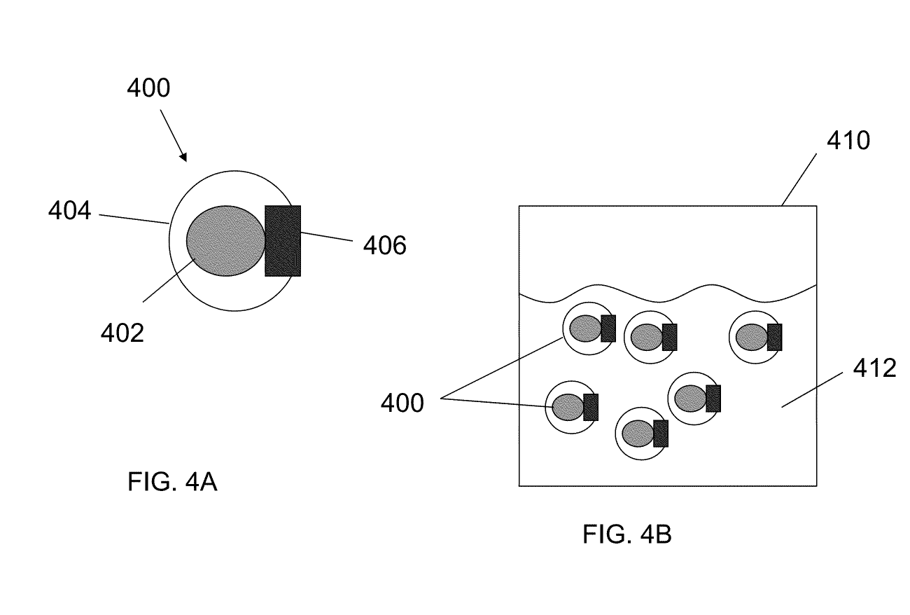

In reference to FIG. 4A, in some embodiments, the materials of the present disclosure may be presented as particles 400 including a photovoltaic hematite junction 404 on a conductive substrate 402, which may serve as a first electrode material, and further including a suitable second electrode material 406 such as platinum or another catalyst metal. The substrate 402 may be in electrical contact with the electrode material 406 to allow electrons to travel from the substrate 402 to the second electrode material 406.

In reference to FIG. 4B, in some embodiments, a plurality of particles 400 may be added to a container 410 containing water 412 to effectuate splitting of water 412 into hydrogen and oxygen atoms upon absorption of light by the particles 400.

It should be noted that the electrodes of the present disclosure with a photovoltaic hematite junction can be utilized in other photovoltaic applications, not just water photoelectrolysis. Solid-state photovoltaic or photoelectrochemical cells in which the generated charge is collected in electronic form, rather than water splitting, could be designed by this same principle. The presently disclosed designs can also be used to supply charge to other electrochemical reactions other than water splitting, including, but not limited to, photosynthesis of other useful molecules or fuels. The materials of the present disclosure may be used in photoelectrochemical synthesis applications in which photo-generated charge is used to drive chemical reactions, in photovoltaic cells to generate electricity, and in solar filters designed to selectively block light.

In some embodiments, photovoltaic junctions of the present disclosure may be used to enhance efficiency of solar cells or other electronic devices. By way of a non-limiting example, the formation of a photovoltaic junction as disclosed herein can improve the efficiency of dye-sensitized solar cell. By depositing a p-type metal oxide on TiO₂ or other materials that were employed as electrode materials, the formation of photovoltaic junction can prevent back transfer of electrons, which could increase photovoltage and photocurrent.

In some embodiments, a method for reducing a turn-on voltage by forming a photovoltaic junction may also be used in other applications such as, for example, coating n-type titanium oxide, TiO₂, on p-type cuperous oxide, Cu₂O, to protect and improve the performance of Cu₂O photoanode. Other examples include, but are not limited to, deposition of a thin n-type metal oxide, such as TiO₂, WO₃ or Fe₂O₃, on a photocathode, such as InP, GaP, GaInP₂ to enhance its efficiency for solar water splitting. Additionally, photoelectrochemical performance of TiO₂, WO₃ or Fe₂O₃ can be improved by coating of NiO, which acts as p-type semiconductor to form photovoltaic junction and catalyst for water oxidation reaction.

In some aspects, the present disclosure provides methods of growing photovoltaic hematite junctions on a substrate. Various gas phase deposition methods may be utilized to form photovoltaic hematite junctions of the present disclosure, including, but not limited to, atomic layer deposition, chemical vapor deposition, pulse laser deposition, evaporation and solution synthesis approach and similar methods.

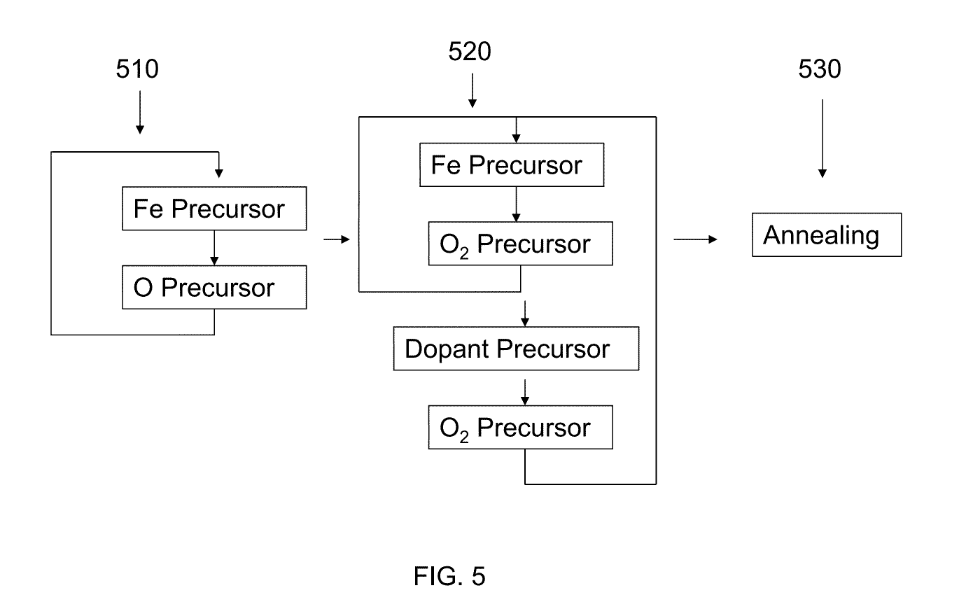

In reference to FIG. 5, in some embodiments, the method for preparing a n-p junction on a substrate includes a step 510 of growing a layer of n-type hematite at a first temperature by exposing a substrate to a pulse of iron precursor, followed by a pulse of oxygen precursor. In some embodiments, the first temperature may be selected based on the reaction temperature of precursors, such as, for example between about 140° C. and about 180° C., to enable formation of n-type hematite from precursors on the substrate surface. In some embodiments, the precursors may be maintained at a temperature from 120° C. to 135° C. to yield appreciable vapor pressure of precursor. Step 510 may be repeated until the layer of the n-type hematite is of a desired thickness.

In step 520, a layer of p-type hematite is deposited over the layer of n-type hematite deposited on the substrate in step 510. In some embodiments, to form p-type hematite, a positive dopant precursor may be introduced to react with hematite. Suitable dopants include, but are not limited to, magnesium (Mg), zinc (Zn), copper (Cu) and calcium (Ca). In some embodiments, the precursors are of high vapor pressure and are reactive toward water vapor at relatively low temperature. Water is typically used as oxygen precursor due to its simplicity and nontoxicity. The growth of p-type hematite may take place at a similar or different temperature from growth of the n-type hematite. In some embodiments, p-type hematite may be grown at a temperature selected based on the reaction temperature of precursors, such as, for example between about 160 C and about 180 C, to enable formation of p-type hematite from precursors. Step 520 may be repeated until the layer of the p-type hematite is of a desired thickness.

In step 530, the n-p hematite junction formed on the substrate in steps 510 and 520 may be annealed Annealing at elevated temperature, such as a temperature between about 500 and about 700° C. crystalizes both n-type and p-type hematite films, which activates photoactivity of the films.

In general, the methods of growing n-p hematite junctions of the present disclosure enable growth of p-type hematite to take place at a mild temperature, between about 120° C. and 135° C. In some embodiments, the methods of the present disclosure may allow the annealing step to proceed at 500° C., which is a significant decrease from a temperature of about 800° C. or higher typically used for annealing p-type hematite. This is advantageous because at this lower temperature n-type hematite is not converted to p-type hematite, therefore resulting in a defined, substantially uniform and defect free interface between the n-type and p-type hematite layers. In some embodiments, the p-type layer follows the contour of the underlying n-type layer without sudden changes of thickness or other visual effects, thus forming a substantially uniform interface between the layers of opposite polarity. In such embodiments, the p-type hematite has a consistent thickness along the entire length of the material. Because the methods of the present disclosure result in a short diffusion length for the dopant, that is a relatively thin thickness of the film, typically less than about 10 nm, and, in some embodiments, less than about 5 nm, the p-type hematite grown as described herein can be annealed at a lower temperature. For example, the presently disclosed methods enable uniform distribution of the positive dopant within hematite film, resulting in shorter diffusion lengths for the dopant. In some embodiments, the dopants are uniformly distributed, without obvious aggregation of dopants (that is, change of concentration of dopant of about 10% or greater.

### EXAMPLES

Examples (actual and simulated) of using the devices and methods of the present disclosure are provided below. These examples are merely representative and should not be used to limit the scope of the present disclosure. A large variety of alternative designs exists for the methods and devices disclosed herein. The selected examples are therefore used mostly to demonstrate the principles of the devices and methods disclosed herein.

### Example 1

### Growth and Characterization of p-Type Hematite

To prepare p-type hematite by atomic layer deposition, bis(ethylcyclopentadienyl) magnesium was used as the Mg precursor (see e.g., Burton, B. B.; Goldstein, D. N.; George, S. M. J. Phys. Chem. C 2009, 113, 1939) and the precursor for Fe was iron tertbutoxide. (see e.g., Bachmann, J.; Jing; Knez, M.; Barth, S.; Shen, H.; Mathur, S.; Gösele, U.; Nielsch, K. J. Am. Chem. Soc. 2007, 129, 9554) For a typical growth, the Mg precursor was introduced once every 5 cycles of repeated pulses of Fe precursors and H₂O.

Series of experiments was performed, including photoelectrochemical (PEC) characterizations and electrochemical impedance measurements, to verify that the Mg-doped hematite was indeed p-type.

As discussed in detail below, the optical absorption was characteristic of hematite without intentional doping (inherently n-type), proving that the inclusion of Mg did not change the optical properties of hematite measurably.

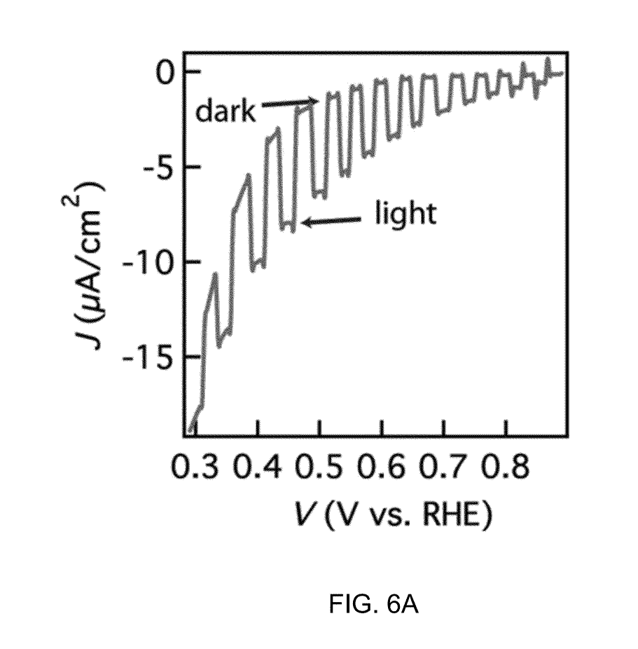

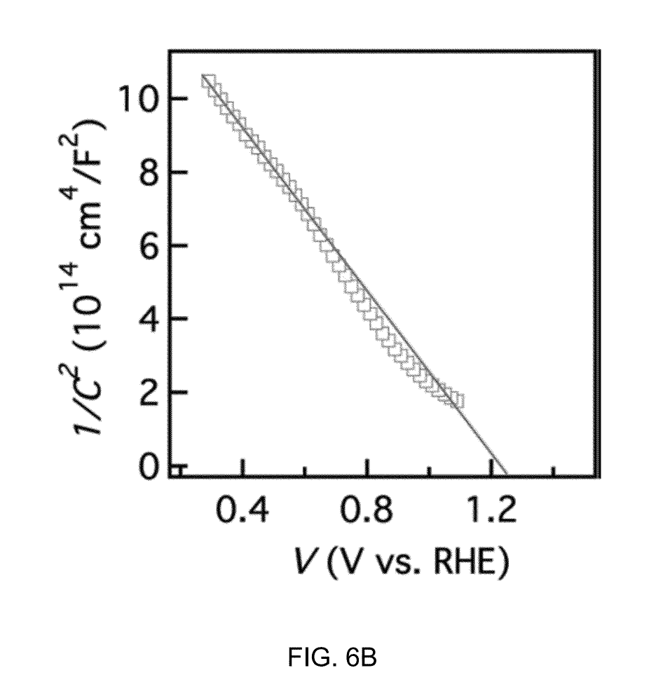

FIG. 6A and FIG. 6B provide Mg-doped hematite characterization data. A cathodic current was measured in Mg-doped hematite under illumination in 1M KOH solution, as shown in FIG. 6A. In the absence of electron scavengers, the cathodic current was due to O₂ reduction. By contrast, cathodic current was not observed under similar measurement conditions by n-type hematite.

Additional evidence that the Mg-doped hematite is of p-type comes from negative slope obtained when the capacitance was plotted against the applied potentials (Mott-Schottky plot), as shown in FIG. 6B, from which a hole concentration of 1.7×10¹⁵ cm³ was calculated. Extrapolation of the Mott-Schottky plot also yielded a flat band potential (Vₜₕ) of 1.24 V versus RHE (reversible hydrogen electrode; all potentials henceforward are relative to RHE unless noted). This value is significantly more positive than that of non-intentionally doped hematite synthesized by ALD (0.67 V) (see e.g. Lin, Y.; Zhou, S.; Sheehan, S. W.; Wang, D. J. Am. Chem. Soc. 2011, 133, 2398.), indicating a considerable shift of the Fermi level toward the valence band edge.

### Example 2

### Growth and Characterization of n-p Hematite Junction

Hematite junctions were formed by directly growing Mg-doped Fe₂O₃ (5 nm) on iron oxide without intentional doping (20 nm), which is inherently n-type due to O vacancies.

Detailed information about the synthesis of Fe₂O₃ by atomic layer deposition (ALD) has been reported in Lin, Y.; Zhou, S.; Sheehan, S. W.; Wang, D. J. Am. Chem. Soc. 2011, 133, 2398. Briefly, the growth was carried out at 180° C., with iron tertbutoxide and H₂O as Fe and O precursors, respectively. It was deposited on fluorine doped tin oxide (FTO; MTI, TEC 15). The Fe precursor was maintained at 130° C. to yield appreciable vapor pressure, and H₂O was used at room temperature. Mg doping was achieved by pulsing bis(ethylcyclopentadienyl)magnesium, which was kept at 92° C. The growth temperature for doped Fe₂O₃ was also 180° C. The pulse time for Mg precursor was 50 ms, and that for H₂O was 15 ms. After each pulse of a precusor, the chamber was purged by ultra high purity Ar for 10 sec.

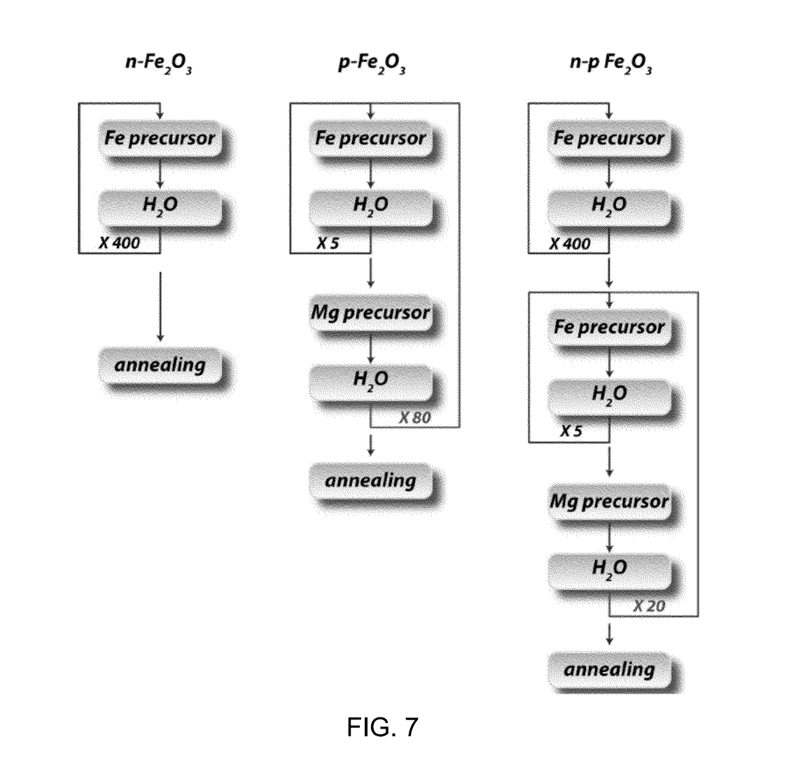

The dopant concentration was adjusted by controlling the ratio of Fe precursor pulses to those of Mg precursor. The ratio was varied between 10 (i.e., 1 cycle of Mg precursor every 10 cycles of Fe precursor) and 2. Cathodic photocurrents were measured on all resulting materials. It was found that 5 cycles of Fe precursor followed by 1 cycle of Mg precursor yielded the best PEC performance. FIG. 7 illustrates embodiment procedures for growth of n-Fe₂O₃, p-Fe₂O₃, and n-p Fe₂O₃

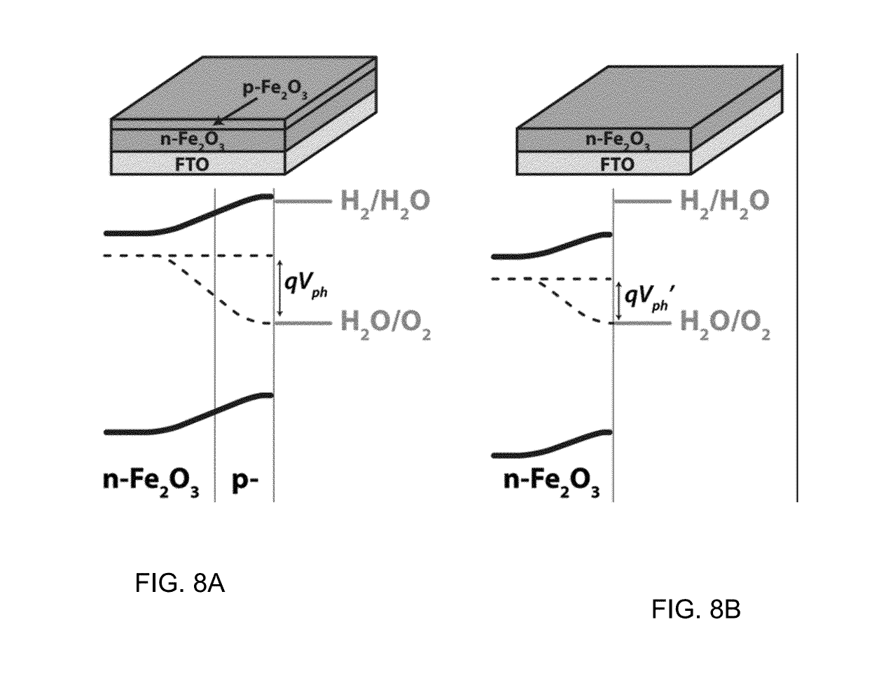

FIG. 8A and FIG. 8B illustrate energy diagrams of a n-p Fe₂O₃ system and a n-Fe₂O₃ on a simplistic planar geometry (with illumination). For a system in vacuum, one can measure a photovoltage up to Vph when an n-p junction exists. In the absence of p-type coating, no photovoltage is expected from n-type hematite. When in contact with H₂O, however, a significant surface potential due to surface adsorption can build up on the surface of n-type hematite. This potential allows for the measurement of a photovoltage of Vph′. As such, for hematite in contact with H₂O, the difference between Vph and Vph′ (ΔVph=Vph−Vph′) would be what one gains by forming a buried n-p junction.

FIG. 8A and FIG. 8B show that even without optimization, this difference is substantial, on the order of hundreds of millivolts (mV), comparable to the effect exhibited by catalysts. In reference to FIG. 8A, the introduction of a p-type layer created a built-in field that did not depend on surface adsorptions, allowing for the measurement of a more substantial photovoltage (Vₚₕ). In comparison, as shown in FIG. 8B, although a built-in field can also be achieved on n-type hematite, its depth and magnitude are sensitive to the nature of the electrolyte.

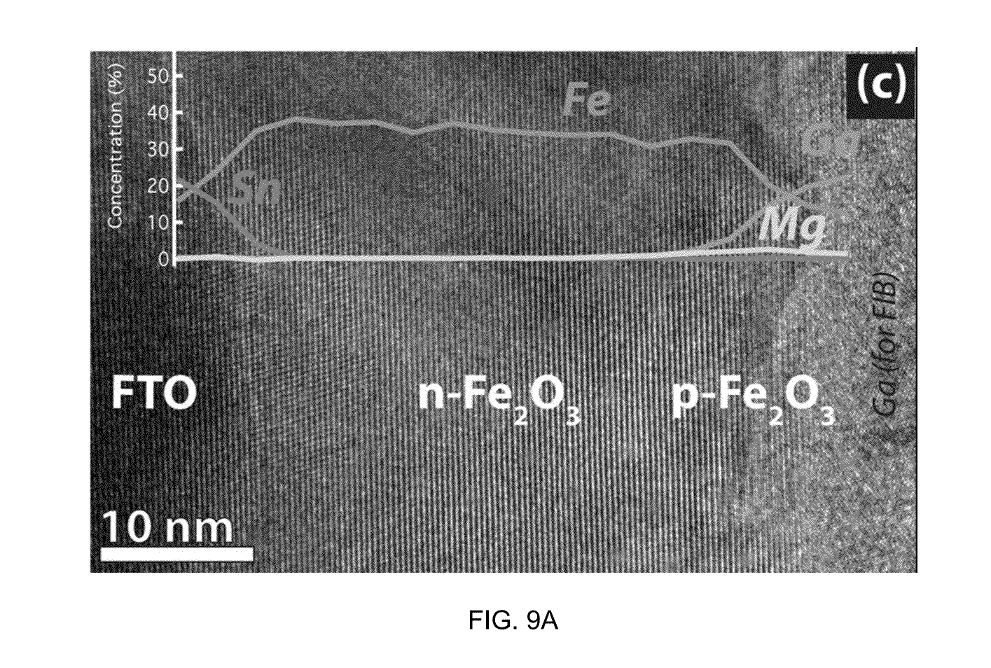

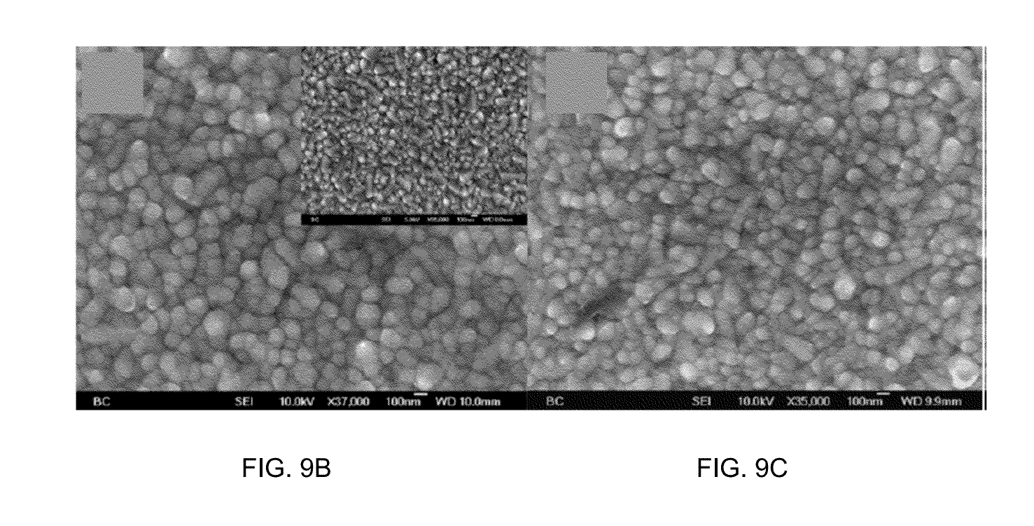

FIG. 9A presents a cross-sectional transmission electron micrograph (TEM) of the hematite junction, including a line-scan of energy dispersive spectra (EDS) of various elements across the film in the inset. The cross section sample as shown in FIG. 8C was prepared using a focused ion beam (FIB, JOEL 4500 multibeam system). A carbon film (˜1 μm in thickness) and W film (˜0.5 μm) were deposited sequentially to minimize ion beam damage during the preparation process. A thin slice (˜15×15 μm span; 1 μm thick) was cut from the planar substrate and transferred to a Cu support with a nano-manipulator (Kleindiek Nanotechnik MM3A). The slice was further thinned to e-beam transparent by low-energy ion beam (5 kV). The specimen was studied by a transmission electron microscope (TEM, JOEL 2010F). As shown in FIG. 9A, a 20 nm thick film was produced by 400 cycles of deposition (measured by Fe precursor pulses), resulting in a Mg concentration of ca. 3%. Moreover, it can be seen from FIG. 8C that no grain boundary was observed between p- and n-type Fe₂O₃. Accordingly, from this data, it appears that the growth of p-type Fe₂O₃ did not introduce additional structural defects.

FIG. 9B and FIG. 9C present SEM images of iron oxide film on fluorine-doped tin oxide (FTO) substrate. Iron oxide film on fluorine-doped tin oxide (FTO) substrate was characterized by a Scanning Electron Microscope (SEM, JSM6340F). FIG. 9B presents an SEM image of non-doped iron oxide film on fluorine-doped tin oxide (FTO) substrate. Inset in FIG. 9B shows the surface morphology of bare FTO substrate. FIG. 9C presents an SEM image of Mg-doped iron oxide film on fluorine-doped tin oxide (FTO) substrate.

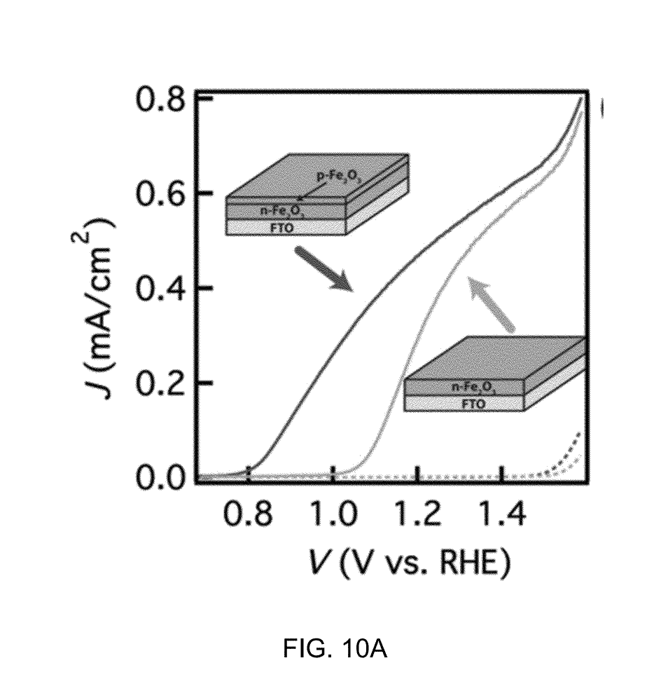

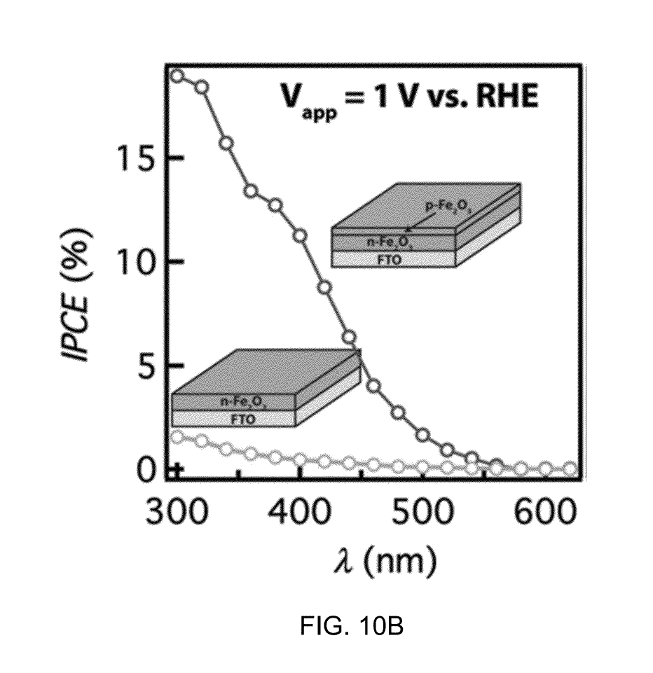

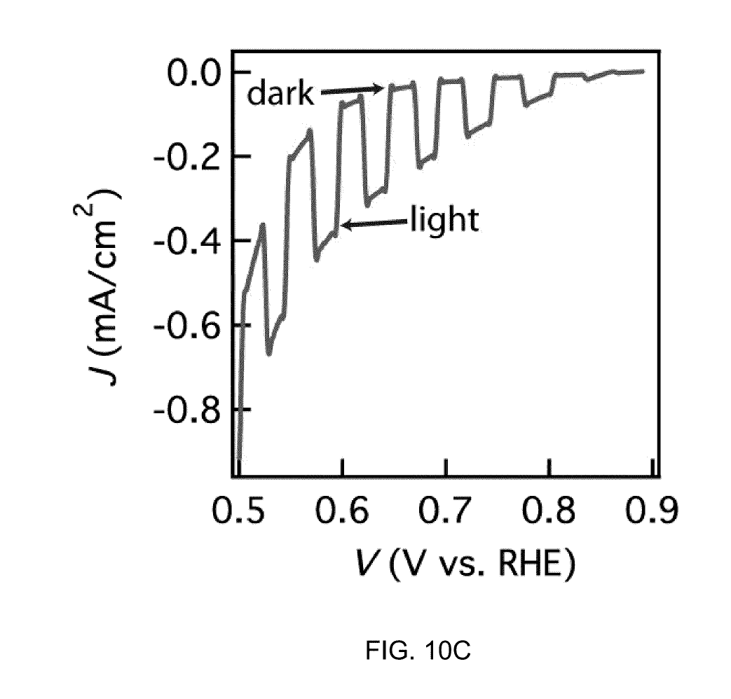

FIG. 10A and FIG. 10B illustrate photoelectrochemical (PEC) characterization data of n-type hematite with and without p-type coating. In this instance, the p-type coating was 5 nm thick. In reference to FIG. 10A, a significant reduction of the turn-on voltage was observed on the sample with p-Fe₂O₃. Data was measured under 1 Sun conditions (100 mW/cm², AM 1.5 G), and dark currents shown in dashed lines. FIG. 10B provides incident photon to charge conversion efficiencies (IPCE) characteristics of these samples at 1 V.

Previously reported procedures were followed to fashion the as-prepared Fe₂O₃ samples into photoelectrodes (Lin, Y.; Zhou, S.; Sheehan, S. W.; Wang, D. J. Am. Chem. Soc. 2011, 133, 2398.) The PEC measurements were performed on a CHI 608C Potentiostat in a three-electrode configuration, with Fe₂O₃ as the working electrode, a Pt mesh as the counter electrode, and a Hg/HgO in 1 M NaOH as the reference electrode. The electrolyte was 1 M KOH solution (pH 13.6 as measured by an Orion 4-Star pH meter (Thermo Scientific). The current flowing into the photoanode was defined as positive. The solution was purged with N₂ for 20 min prior to a measurement.

In a typical experiment, the potential was linearly swept from 0.7 V to 1.6 V vs. RHE at a scan rate of 10 mV/s for n-type and n-p Fe₂O₃. The potential was scanned from 1.0 to 0.3 V vs RHE at a scan rate of 10 mV/s for Mg-doped Fe₂O₃. The light source was a solar simulator (Oriel, model 96000) equipped with AM 1.5 filter with the illumination intensity adjusted to 100 mW/cm² by a thermopile optical detector (Newport, Model 818P-010-12). The incident photonto-charge conversion efficiencies (IPCE) were measured using a solar simulator (Oriel, model 96000) coupled with a monochromator (Oriel Cornerstone 260). The intensity of the monochromatic light was measured by a calibrated Si detector (Oriel, model 71640). The working electrode was biased at 1.0 V (vs. RHE) using the same configuration as described above.

Electrochemical impedance spectroscopy (EIS) measurements were performed using a three-electrode configuration on a CHI 608C as described above. A sinusoidal voltage perturbation, with amplitude of 5 mV and frequencies varying from 100 kHz to 1 Hz, was superimposed onto the applied bias. The impedance was recorded at biases ranging between 1.1 and 1.8 V vs RHE.

The open circuit voltage decay was carried out using a three-electrode configuration. The open circuit voltage of working electrodes was first stabilized for 10 min under illumination. Afterward the light source was turned off The decay of open circuit voltage was recorded continuously for the next 10 min.

PEC measurements revealed a difference in the turn-on characteristics between Fe₂O₃ with and without the p-type coating, as shown in FIG. 10A. While no significant photocurrent was detected below 1 V for n-type Fe₂O₃, with Mg-doped Fe₂O₃ coating it exhibited a turn-on voltage of ca. 0.8 V, representing a −0.2 V shift. The IPCE data were also recorded at 1 V applied potential to verify this effect, as shown in FIG. 10B. The reduction of required bias is significant because it is comparable to what has been achieved by improving charge transfer through additions of catalysts.

In reference to FIG. 10C, further, Mg-doped Fe₂O₃ was studied in a PEC cell, where the electrolyte was 1 M KOH solution without or with addition of 0.5 M H₂O₂ as an electron scavenger. The potential was scanned from 1.0 to 0.3 V vs RHE at a scan rate of 10 mV/s. Addition of electron scavengers such as H₂O₂ increased the current significantly (by >100 times) compared with that measured in KOH-only solution.

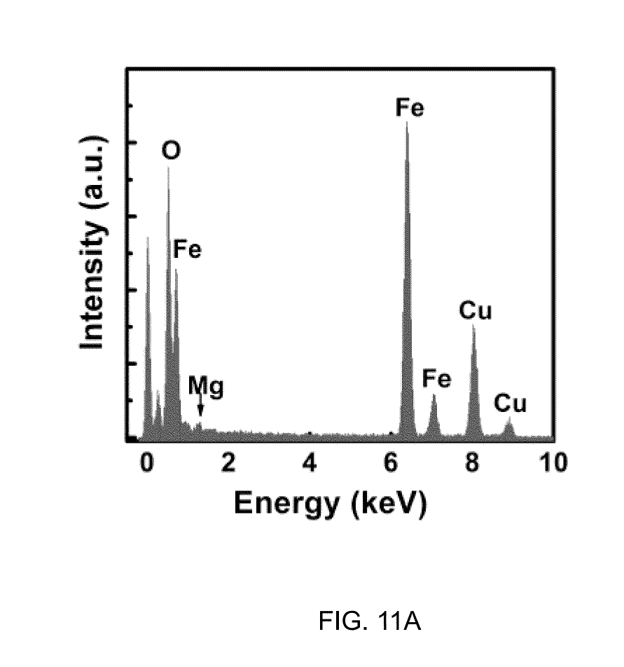

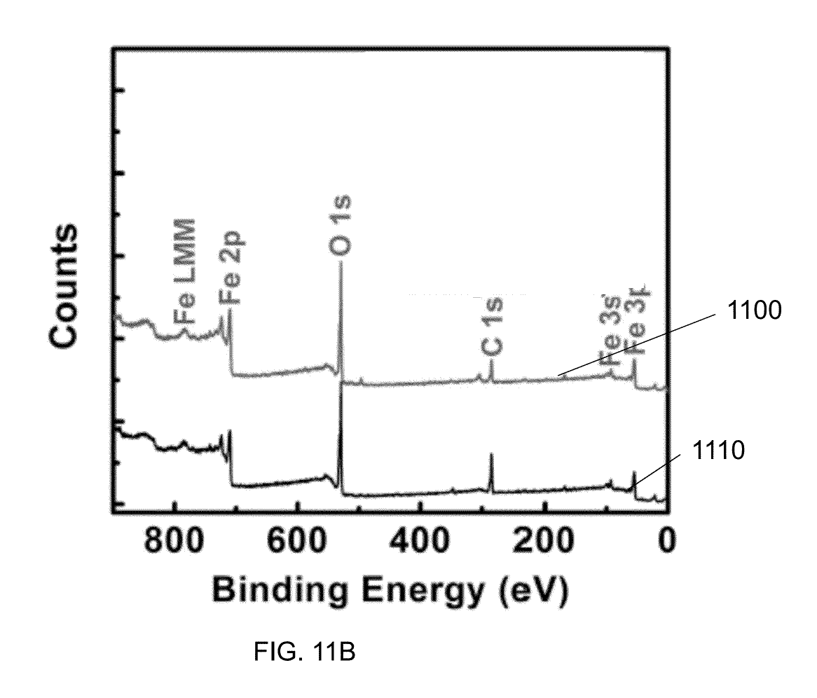

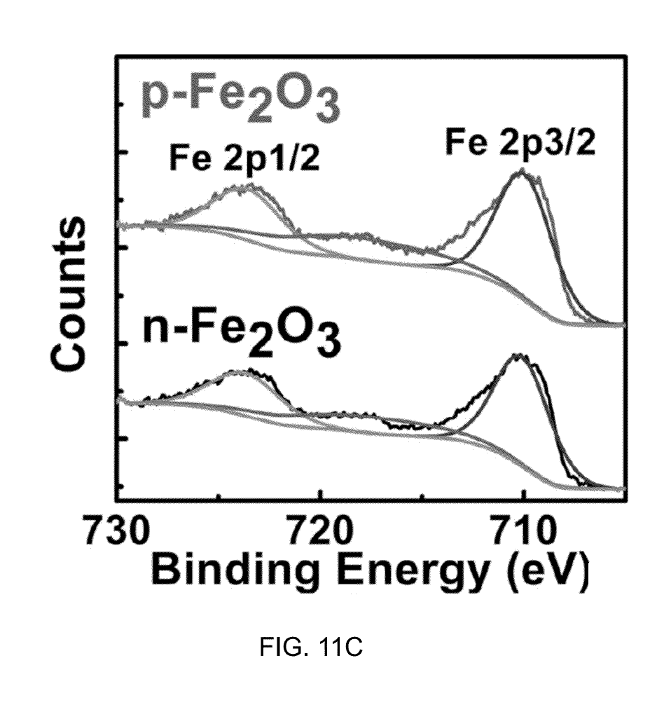

FIG. 11A and FIG. 11B present results of elemental analysis of Fe₂O₃ with and without Mg doping, respectively. The analysis was carried out by energy dispersive spectroscopy (EDS, attached to TEM, JOEL 2010F) and X-ray photoelectron Spectrometer (XPS, Kratos AXIS Ultra Imaging Spectrometer). FIG. 11A presents an EDS spectrum of Mg-doped Fe₂O₃, showing the existence of Mg (atomic concentration 3%). FIG. 11B is a survey scan of XPS data of Fe₂O₃ with (1100) and without (1110) Mg doping. FIG. 11C is a magnified view of the Fe 2p region of Fe₂O₃ with (p-Fe₂O₃) and without (n-Fe₂O₃) Mg doping of FIG. 11B.

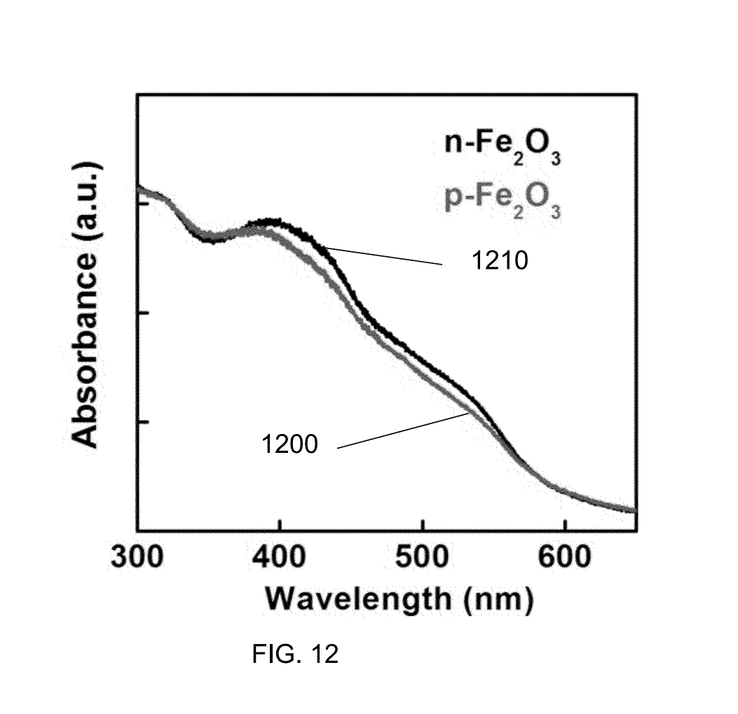

FIG. 12 presents optical absorption spectra of Fe₂O₃ with (1200) and without (1220) Mg doping. The absorption spectra of Mg-doped Fe₂O₃ and Fe₂O₃ without intentional dopants were recorded using a spectrometer (Ocean Optics USB 4000). As shown in FIG. 12, within measurement errors, there were no significant differences between these two types of samples.

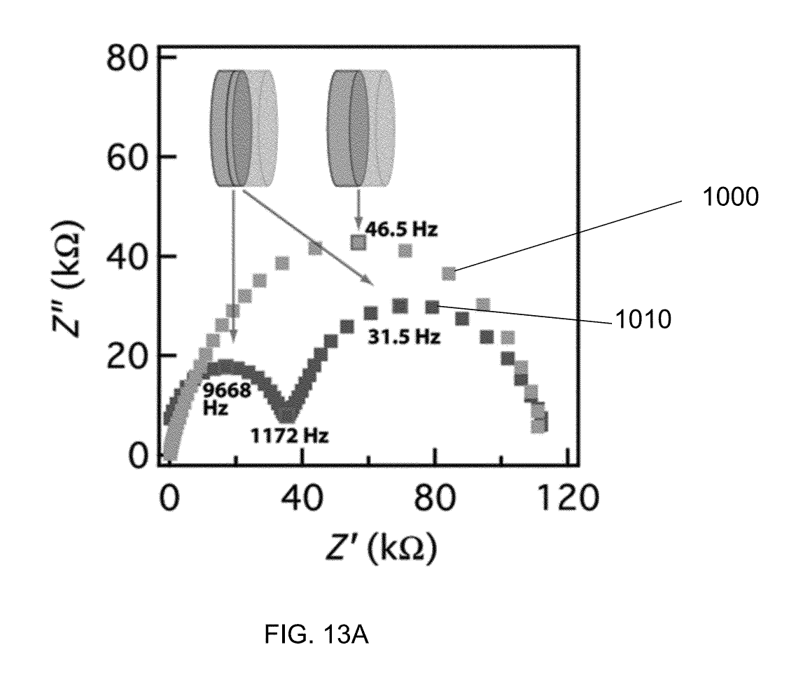

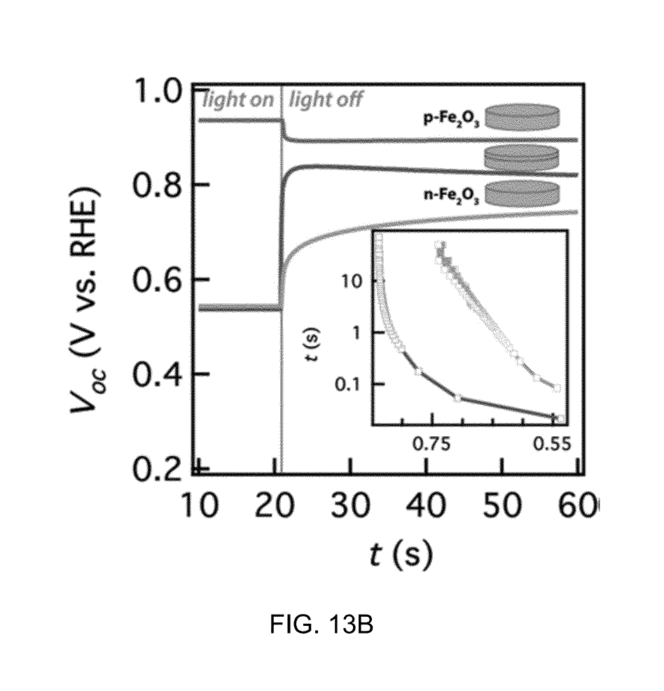

FIG. 13A and FIG. 13B demonstrate visualization of the n-p junction within hematite. In reference to FIG. 13A, a clear difference is visible between the Nyquist plot 1000 of n-type hematite and the Nyquist plot 1010 of n-p Fe₂O₃ (measured at 1.7 V vs RHE). To assist viewing, the assignments of the semicircles are illustrated by schematics of device structures (H₂O shown as translucent layer on the right hand side). Several key data points are highlighted, with the corresponding frequencies labeled. Origin of the semicircles can be attributed to the depletion of Fe₂O₃ due to the contact with the electrolyte but not the Helmholtz double layer because of the frequency range (peaking at ca. 46 Hz) within which it was measured. In contrast, two semicircles were observed on Fe₂O₃ with the n-p junction, one in the frequency range (peaking at ca. 31 Hz) similar to that of n-Fe₂O₃, the other in the high frequency range (peaking at ca. 10 kHz), which was attributed to the n-p junction. Because the measurements were performed in dark, the system impedance was dominated by charge transfer at potentials below 1.6 V, and that was why the plots in FIG. 13A at 1.7 V were obtained.

FIG. 13B presents open circuit voltage decay data for p-, n-, and n-p Fe₂O₃. Time constant of the decay plotted in semilogarithm scale with V vs RHE x-axis is shown in the inset. Label for x-axis. This data illustrates the existence of the built-in field based on how the field affects charge behaviors. Under illumination, this field facilitates charge separation; conversely, under transient conditions when the illumination is stopped, the junction should be a preferable site for photogenerated electrons and holes to recombine. As such, one would expect accelerated open circuit voltage (V_{oc}) decay when illumination is removed. This was indeed observed. Shown in FIG. 13B are the comparison between p-, n-, and n-p Fe₂O₃. That a negative change of the open circuit voltage was observed upon removing illumination from Mg-doped Fe₂O₃ further supports that the Mg-doped Fe₂O₃ was indeed p-type Fe₂O₃. Also it should be noted that the nature of the n-p Fe₂O₃ behavior is similar to n-Fe₂O₃ for two reasons: the film is predominantly n-type with a thin p-type coating, and the measurement conditions favor hole transfer to the solution.

As shown in the inset of FIG. 13B, using the methodology developed by Bisquert et al. (Zaban, A.; Greenshtein, M.; Bisquert, J. Chem Phys Chem 2003, 4, 859), the open circuit voltage decay for n-p Fe₂O₃ is faster than n-Fe₂O₃ by at least an order of magnitude. The fast decay kinetics is indicative of insignificant charge trapping when illuminated and, hence, effective charge separation under water splitting conditions. It should also be emphasized that the lower bound of the time constant (˜100 ms) is limited by the apparatus used. The process may take place on a faster time scale.

### Example 3

### Control Experiments

To determine whether the difference in PEC behavior in Example 2 was due to the total film thickness (20 nm for bare hematite and 25 nm for that with Mg-doped hematite), additional 5 nm n-hematite was grown on top of a 20 nm thick pregrown n-type sample, resulting in a total thickness of 25 nm. The growth procedure was identical to the two-step growth of n-p junction samples.

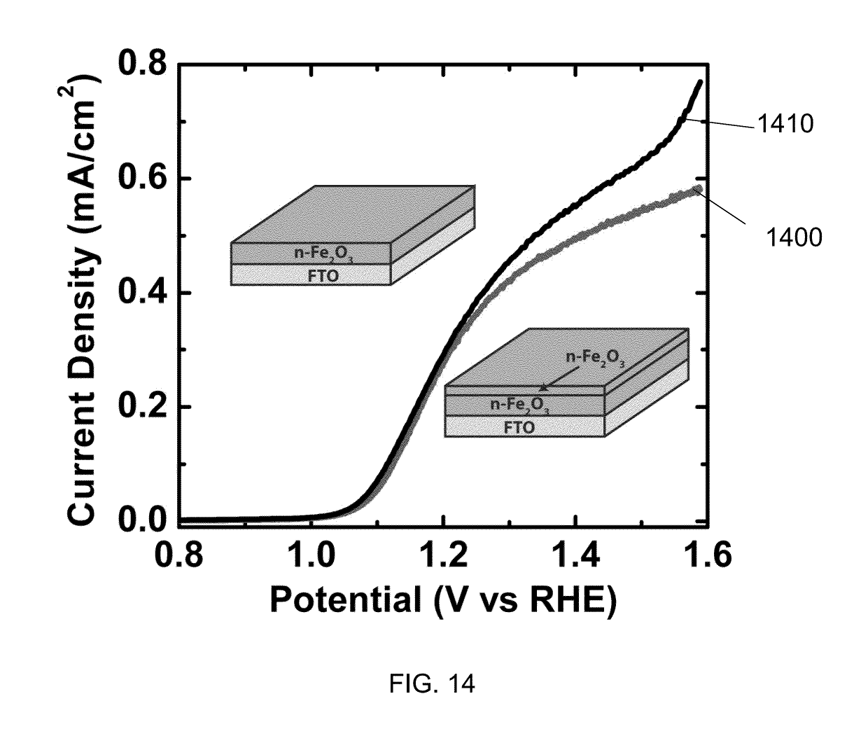

FIG. 14 is a comparison of current density data for 20 mm thick n-type hematite film (1400) and 25 mm thick n-type hematite film (1410). As shown in FIG. 14, when an additional n-type Fe₂O₃ (5 nm) was deposited on an existing 20 nm thick film, a slightly lower saturation current was measured. This result is in line with expectation that thicker Fe₂O₃ will lead to reduced photocurrents due to poorer charge collection. As such, the turn-on voltage shift in the samples with p-type hematite film, as shown in FIG. 10A and FIG. 10B, is not a result of film thickness difference.

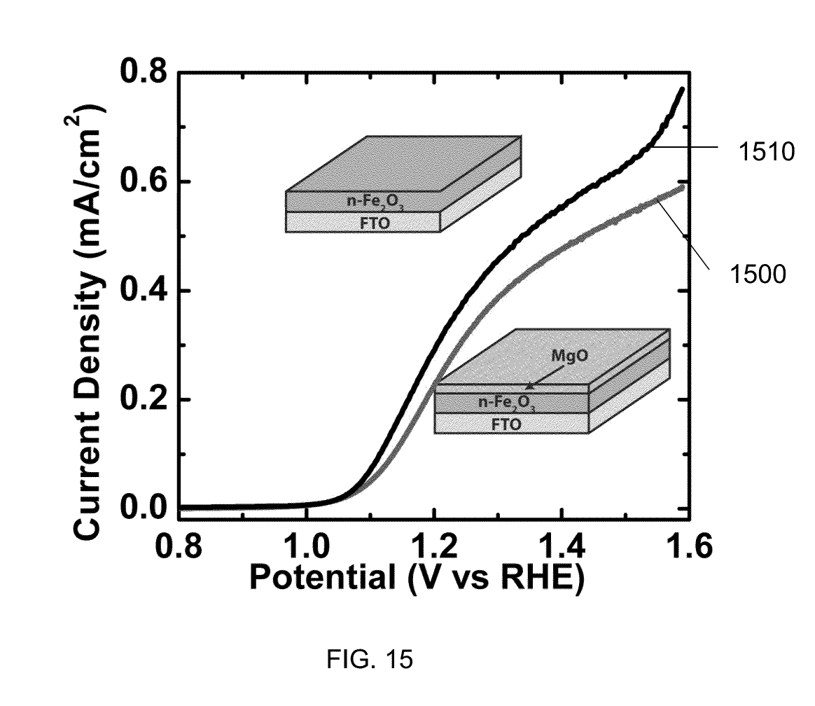

FIG. 15 presents a comparison of current density data for Fe₂O₃ with (1500) and without (1510) MgO capping layer. To determine whether the intended Mg doping could function as a passivation instead, n-type Fe₂O₃ was prepared with MgO capping layer (thickness: 20 cycles MgO growth. Thicker MgO coating with 40 cycles or 100 cycles growth has also been tried.). As shown in FIG. 15, reduced photocurrents were observed in the samples, which should be due to increased charge transfer resistance by MgO. Accordingly, it does not appear that the intended Mg doping could function as a passivation instead.

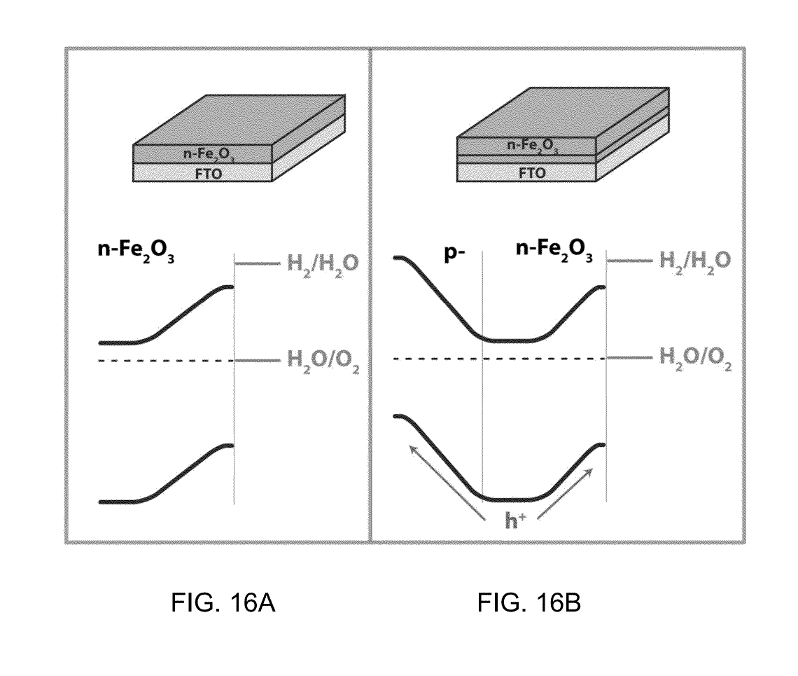

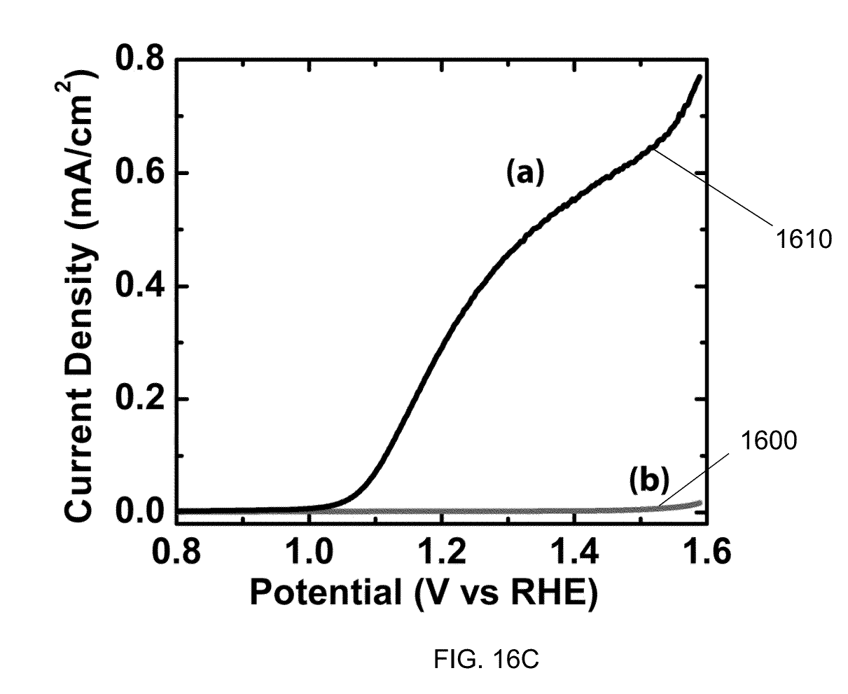

To determine whether the sequence of the hematite layers impacts performance of the devices, samples were prepared with the p-type layer between n-type Fe₂O₃ and FTO instead of between n-type Fe₂O₃ and H₂O. FIG. 16C is a comparison of photoelectrodes with (1600) and without (1610) a p-type layer between n-type Fe₂O₃ and FTO, with the corresponding device structures and band diagrams shown in FIG. 16A and FIG. 16B. As can be seen from FIG. 16C, the photocurrent was suppressed in sample with a p-type layer between n-type Fe₂O₃ and FTO, because the p-type layer formed a trap to compete with surface H₂O in receiving photogenerated holes. Accordingly, devices with the p-type layer between n-type Fe₂O₃ and FTO may be used for example for water reduction reactions.

### Example 4

### APCE Measurements

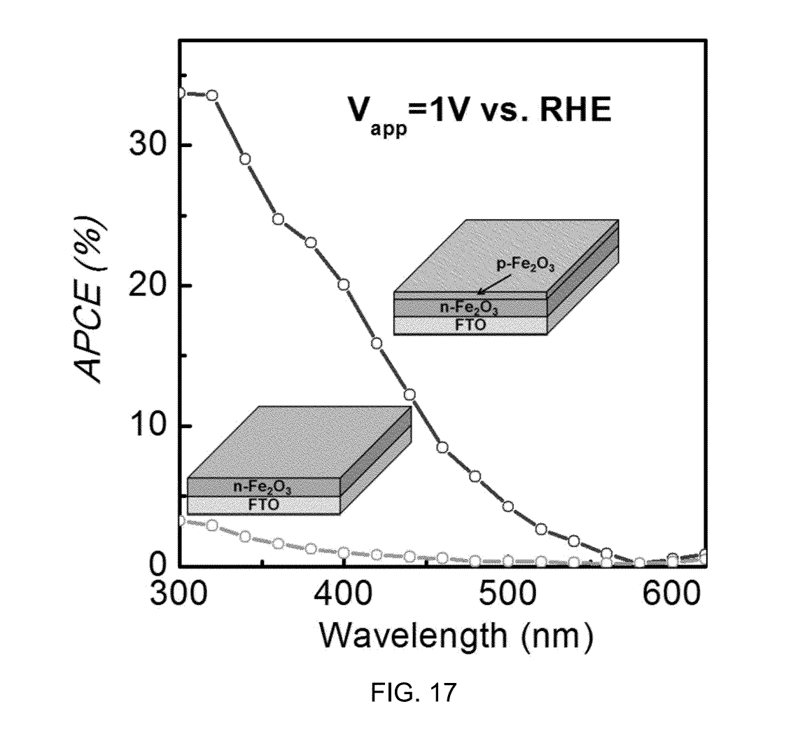

Absorbed photon-to-current conversion efficiencies (APCE) were calculated for iron oxide on FTO substrate using following equation:

$$APCE = \frac{IPCE}{1 - {10}^{- A}} ,$$

where A is the absorbance. FIG. 17 illustrates APCE of iron oxide with and without p-type coating measured at 1V.

In some embodiments, a photovoltaic device of the present disclosure includes a substrate and a hematite photovoltaic junction deposited on the substrate having a uniform interface between hematite layers of different polarity. In some embodiments, the hematite photovoltaic junction is a n-p unction comprising a layer of n-type hematite deposited over the substrate; and a layer of p-type hematite deposited over the n-type hematite.

In some embodiments, a device for splitting water of the present includes a first compartment; a first electrode disposed in the first compartment, the first electrode comprising a hematite photovoltaic junction having a uniform interface between hematite layers of different polarity deposited on a substrate; and a second compartment having a second electrode, wherein the first compartment and the second compartment are separated by a semi-permeable membrane.

In some embodiments, a method of growing a photovoltaic hematite junctions on a substrate includes utilizing a gas phase deposition to deposit an n-type hematite over a substrate; depositing a p-type hematite over the n-type hematite; and annealing the resulting n-p hematite junction at a temperature selected to preserve the n-type hematite.

In some embodiments, a photovoltaic device includes a substrate and a photovoltaic junction deposited on the substrate, the photovoltaic junction having a n-type hematite and a p-type hematite.

In some embodiments, a device for splitting water includes a first compartment having a first electrode, the electrode comprising a substrate, and a photovoltaic junction deposited on the substrate, the photovoltaic junction having a n-type hematite and a p-type hematite, a second compartment having a second electrode counter to the first electrode, and a semi-permeable membrane separating the first compartment and the second compartment.

In some embodiments, a method of growing a photovoltaic hematite junctions on a substrate that includes the steps of depositing via a gas phase deposition method a n-type hematite over a substrate, depositing via a gas phase deposition method a p-type hematite over the n-type hematite, and annealing the resulting n-p hematite junction at a temperature selected to preserve the n-type hematite.

In some embodiments, a photovoltaic device that includes one or more particles, each particle formed from a hematite photovoltaic junction deposited on a substrate and an electrode material in electrical contact with the substrate.

All patents, patent applications, and published references cited herein are hereby incorporated by reference in their entirety. It will be appreciated that several of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A photovoltaic device comprising:
a substrate; and
a photovoltaic junction deposited on the substrate, the photovoltaic junction having a n-type hematite and a p-type hematite.

2. The photovoltaic device of claim 1 wherein an interface between the n-type hematite and the p-type hematite is substantially uniform.

3. The photovoltaic device of claim 1 wherein an interface between the n-type hematite and the p-type hematite is substantially defect free.

4. The photovoltaic device of claim 1 wherein n interface between the n-type hematite and the p-type hematite is substantially grain boundary free.

5. The photovoltaic device of claim 1 wherein an entire length of the p-type hematite has a consistent thickness.

6. The photovoltaic device of claim 1 wherein the substrate is a metal oxide.

7. The photovoltaic device of claim 1 wherein the substrate is a semiconductor.

8. The photovoltaic device of claim 1 wherein the substrate comprises a plurality of connected and spaced apart nanobeams linked together at an angle of about 90°.

9. A device for splitting water comprising:
a first compartment having a first electrode, the electrode comprising a substrate, and a photovoltaic junction deposited on the substrate, the photovoltaic junction having a n-type hematite and a p-type hematite;
a second compartment having a second electrode counter to the first electrode; and
a semi-permeable membrane separating the first compartment and the second compartment.

10. The device of claim 9 wherein an interface between the n-type hematite and the p-type hematite is substantially uniform.

11. The device of claim 9 wherein an interface between the n-type hematite and the p-type hematite is substantially defect free.

12. The device of claim 9 wherein an interface between the n-type hematite and the p-type hematite is substantially grain boundary free.

13. The device of claim 9 wherein an entire length of the p-type hematite has a consistent thickness.

14. The device of claim 9 wherein the substrate is a metal oxide.

15. The device of claim 9 wherein the substrate is a semiconductor.

16. The device of claim 9 wherein the substrate comprises a plurality of connected and spaced apart nanobeams linked together at an angle of about 90°.

17. A method of growing a photovoltaic hematite junctions on a substrate comprising:
depositing via a gas phase deposition method a n-type hematite over a substrate;
depositing via a gas phase deposition method a p-type hematite over the n-type hematite; and
annealing the resulting n-p hematite junction at a temperature selected to preserve the n-type hematite.

18. The method of claim 17 wherein the depositing of the p-type hematite is carried out at a temperature between about 120° C. and about 135° C.

19. The method of claim 17 wherein the annealing step is carried out at a temperature between about 500° C. and about 700° C.

20. A photovoltaic device comprising one or more particles, each particle formed from a hematite photovoltaic junction deposited on a substrate and an electrode material in electrical contact with the substrate.
